(19) United States
(12) Patent Application Publication
(10) Pub. No.: US 2017/0199252 A1
(43) Pub. Date: Jul. 13, 2017

(54) HALL SENSOR

(71) Applicant: SII Semiconductor Corporation, Chiba-shi (JP)

(72) Inventors: Takaaki HIOKA, Chiba-shi (JP); Tomoki HIKICHI, Chiba-shi (JP)

(21) Appl. No.: 15/469,789

(22) Filed: Mar. 27, 2017

Related U.S. Application Data
(63) Continuation of application No. PCT/JP2015/074318, filed on Aug. 28, 2015.

(30) Foreign Application Priority Data
Sep. 30, 2014 (JP) 2014-202015

(51) Int. Cl. G01R 33/07; H01L 43/06

(52) U.S. Cl. CPC G01R 33/075; H01L 43/06

(57) ABSTRACT

A Hall sensor includes a Hall element and a heat source element in a circuit configured to drive the semiconductor Hall element, and capable of eliminating an offset voltage without increasing a chip size. In the Hall sensor, a Hall element control current flowing between one pair of terminals out of two pairs and a Hall element control current flowing between another pair of terminals cross each other as vectors, the Hall element has a shape that is line-symmetrical to the straight line along a vector sum of the Hall element control current and the Hall element control current, and the heat source element is arranged so that the center of the heat source is positioned on the straight line along the vector sum of the Hall element control current and the Hall element control current.

### RELATED APPLICATIONS

The present application is a continuation of International Application PCT/JP2015/074318, with an international filing date of Aug. 28, 2015, which claims priority to Japanese Patent Application No. 2014-202015 filed on Sep. 30, 2014, the entire contents of which are incorporated herein by reference.

### BACKGROUND OF THE INVENTION

Technical Field

The present invention relates to a semiconductor Hall element and a Hall sensor including a circuit configured to drive the semiconductor Hall element, in particularly, to a Hall sensor capable of eliminating an offset voltage.

Background Art

First, the principle of magnetic detection by a Hall element is described. When a magnetic field is applied perpendicularly to a current flowing through a substance, an electric field (Hall voltage) is generated in a direction perpendicular to both the current and the magnetic field. The principle of the magnetic detection by the Hall element is to acquire an intensity of the magnetic field based on a magnitude of the Hall voltage.

In a Hall element as illustrated in FIG. 6, a Hall voltage VH appearing on a voltmeter 3 is represented as:

VH=μB(W/L)Vdd,

where W and L represent respectively a width and a length of a magnetism sensing portion 1 of the Hall element, μ represents electron mobility, Vdd represents a voltage applied by a power supply 2 for supplying a current, and B represents an applied magnetic field. A coefficient proportional to the applied magnetic field B corresponds to a magnetic sensitivity, and hence a magnetic sensitivity Kh of this Hall element is represented as:

Kh=μ(W/L)Vdd.

Meanwhile, in an actual Hall element, an output voltage comes out even in the absence of the applied magnetic field. The voltage output under a zero magnetic field is called offset voltage. Reason for the appearance of the offset voltage is considered to be imbalance of electric potential distribution inside the element due to, for example, mechanical stress applied to the element from the outside thereof or misalignment occurring in a manufacturing process.

The offset voltage is generally compensated for by the following method.

FIG. 7 is a circuit diagram for illustrating the principle of an offset cancellation circuit utilizing spinning current. A Hall element 10 has a symmetrical shape and includes four terminals T1, T2, T3, and T4 so that a control current is caused to flow between one pair of input terminals and an output voltage is obtained between the other pair of output terminals. When one pair of the terminals T1 and T2 of the Hall element serve as control current input terminals, the other pair of the terminals T3 and T4 serve as Hall voltage output terminals. In this case, when a voltage Vin is applied between the input terminals, an output voltage Vh+Vos is generated between the output terminals, where Vh represents a Hall voltage proportional to a magnetic field generated by the Hall element and Vos represents an offset voltage. Further, with the terminals T3 and T4 serving as the control current output terminals and the terminals T1 and T2 serving as the Hall voltage output terminals, when the input voltage Vin is applied between the terminals T3 and T4, a voltage −Vh+Vos is generated between the output terminals. Reference symbols S1 to S4 denote sensor terminal switching means, and one of terminals N1 and N2 is selected by a switching signal generator 11.

By subtracting one output voltage from the other which are obtained by the currents flowing in two directions described above, the offset voltage Vos may be cancelled to obtain an output voltage 2 Vh proportional to the magnetic field (see, for example, Patent Literature 1).

However, the offset voltage may not completely be cancelled by this offset cancellation circuit. A description is now given of a reason therefor.

The Hall element is represented as an equivalent circuit illustrated in FIG. 8. Specifically, the Hall element may be represented as a bridge circuit in which the four terminals are connected via four resistors R1, R2, R3, and R4. Based on this model, a description is given of the cancellation of the offset voltage by subtracting one output voltage from the other which are obtained by the currents flowing in the two directions as described above.

When the voltage Vin is applied between the one pair of terminals T1 and T2 of the Hall element, the following Hall voltage is output between the other pair of terminals T3 and T4:

Vouta=(R2*R4−R1*R4)/(R1+R4)/(R2+R3)*Vin,

Meanwhile, when the voltage Vin is applied between the terminals T3 and T4, the following Hall voltage is output between the terminals T1 and T2:

Voutb=(R1*R3−R2*R4)/(R3+R4)/(R1+R2)*Vin,

Then, the difference between the output voltages for the two directions is acquired as:

Vouta−Voutb=(R1−R3)*(R2−R4)*(R2*R4−R1*R3)/(R1+R4)/(R2+R3)/(R3+R4)/(R1+R2)*Vin.

Thus, the offset voltage may be cancelled even when the respective resistors R1, R2, R3, and R4 of the equivalent circuit are different from each other, as long as R1=R3 or R2=R4. In this case, it is assumed that the respective resistance values do not change even when the terminals to be applied with the voltage are changed. However, when this assumption is not satisfied, for example, when R1=R3 is established for one direction but this relationship is not established for the other direction, the difference may not be made zero, and hence the offset may not be cancelled. A specific description is further given of one of reasons why the offset may not be cancelled by changing the application directions of the voltage.

The Hall element generally has such a structure that a peripheral portion of an N-type doped region, which is to serve as the Hall element magnetism sensing portion, is surrounded by a P-type doped region for isolation. When a voltage is applied between the Hall current application terminals, a depletion layer expands at a boundary between the Hall element magnetism sensing portion and its peripheral portion. No Hall current flows in the depletion layer, and hence in a region of the expanding depletion layer, the Hall current is suppressed to increase the resistance. Further, the width of the depletion layer depends on the applied voltage. Accordingly, the resistance values of the resistors R1, R2, R3, and R4 of the equivalent circuit illustrated in FIG. 8 change depending on the voltage application direction, and hence in some cases, the offset cancellation circuit may not cancel a magnetic offset.

There may be employed a method involving arranging depletion layer control electrodes around and above the element, and adjusting voltages applied to the respective electrodes, to thereby suppress the depletion layer from extending into the Hall element (see, for example, Patent Literature 2).

### CITATION LIST

### Patent Literature

[PTL 1] JP 06-186103 A

[PTL 2] JP 08-330646 A

### SUMMARY OF THE INVENTION

### Technical Problem

When the temperature in the Hall element 10 is not uniform, but has a distribution, the resistance in the Hall element 10 is not uniform, either, because the temperature is not uniform, the resistance value is low in some locations low and high in some locations. An attempt to cancel the offset by the spinning current thus fails since the resistance values of the resistors R1, R2, R3, and R4 have been changed by the temperature.

Accordingly the offset voltage may not be eliminated by the spinning current method disclosed in Patent Literature 1 in the Hall sensor including the Hall element and elements serving as heat sources in a circuit configured to drive the Hall element since the temperature distribution is generated in the Hall element 10 due to the influence of heat generation.

Moreover, the resistance values may be adjusted by the method disclosed in Patent Literature 2, but the method uses the plurality of depletion layer control electrodes and requires a complex control circuit, and hence has such a problem that the chip size increases, which leads to an increase in cost.

In view of the above, the present invention has an object to provide a Hall sensor including elements serving as heat sources out of components of a circuit configured to drive a Hall element, and capable of cancelling an offset by spinning current even when a temperature distribution is generated in a Hall element 120 due to the influence of heat generation, without a complex compensation circuit and an increase in chip area for separation.

### Solution to Problem

In order to solve the above-mentioned problem, according to an embodiment of the present invention, there is provided a Hall sensor, including:

a Hall element arranged on a semiconductor substrate;

an element, which is arranged around the Hall element, and serves as a heat source; and

two pairs of terminals, which are arranged on the Hall element, and serve both as control current input terminals and Hall voltage output terminals, in which:

a Hall element control current 1 caused to flow between one pair of the terminals out of the two pairs of the terminals and a Hall element control current 2 caused to flow between another pair of the terminals cross each other as vectors;

the Hall element has a shape that is line-symmetrical about a straight line along a vector sum of the Hall element control current 1 and the Hall element control current 2; and

the element serving as the heat source is arranged so that a center of the heat source is positioned on the straight line along the vector sum of the Hall element control current 1 and the Hall element control current 2.

### Advantageous Effects of the Invention

Through use of the above-mentioned measures, in the Hall sensor including elements serving as the heat sources out of components of the circuit configured to drive the Hall element, even when a temperature distribution is generated in the Hall element due to the influence of the heat generation, the offset voltage can be eliminated by the spinning current.

Moreover, since a complex circuit is not used and the distance between the heat source and the Hall element does not increase, the offset voltage can be eliminated, the chip size can be reduced and the cost can be suppressed.

### BRIEF DESCRIPTION OF THE DRAWINGS

FIG. 1 is a plan view for illustrating a Hall sensor according to a first embodiment of the present invention.

FIG. 2 is a plan view for illustrating a Hall sensor according to a second embodiment of the present invention.

FIG. 3 is a plan view for illustrating a Hall sensor according to a third embodiment of the present invention.

FIG. 4 is a plan view for illustrating a Hall sensor according to a fourth embodiment of the present invention.

FIG. 5 is a graph for showing a relationship between an offset voltage by a spinning current and a temperature distribution in order to explain a positional relationship between a Hall element and a heat source.

FIG. 6 is a diagram for illustrating the principle of the ideal Hall effect.

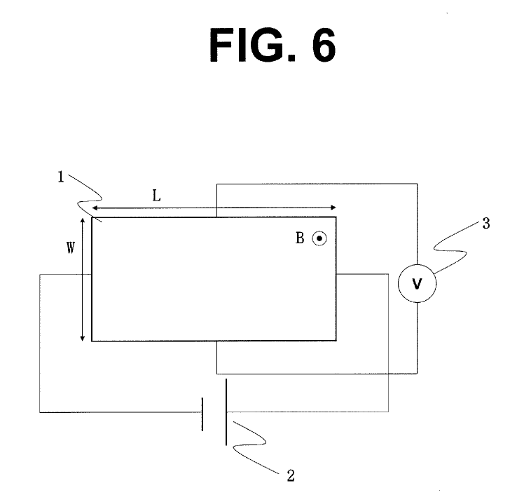

FIG. 7 is a diagram for illustrating a method of eliminating the offset voltage by the spinning current.

FIG. 8 is a diagram of an equivalent circuit for illustrating the offset voltage of the Hall element.

### DETAILED DESCRIPTION OF THE PREFERRED EMBODIMENTS

Embodiments of the present invention are described in detail with reference to the drawings.

### First Embodiment

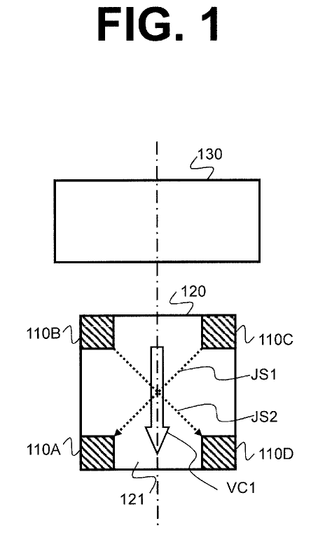

FIG. 1 is a plan view for illustrating a Hall sensor according to a first embodiment of the present invention. The Hall sensor includes a Hall element configured to sense magnetism and a circuit configured to drive or control the Hall element.

First, a description is given of a shape of the Hall element. As illustrated in FIG. 1, a Hall element 120 includes, on a semiconductor substrate, a magnetism sensing portion constructed by a square N-type doped region 121 and control current input terminals and Hall voltage output terminals 110A, 110B, 110C, and 110D constructed by N-type highly-doped regions having the same shape, which are arranged at respective vertices of the square magnetism sensing portion. The Hall element 120 is configured as described above, resulting in a symmetrical Hall element.

A description is now given of a positional relationship between the Hall element and a heat source. A circuit configured to drive the Hall element 120 is arranged on the substrate on which the Hall element 120 is formed. The circuit often includes an element serving as a heat source 130. For example, when an internal circuit of the semiconductor Hall sensor uses, instead of a power supply voltage, an internal power supply voltage generated by stepping down the power supply voltage by a voltage regulator, the voltage regulator may be the heat source. Further, a resistor element, through which a large current flows, or other elements may be the heat source. Thus, as illustrated in FIG. 1, a center of the heat source 130 is aligned with a straight line along a vector sum VC1 of Hall element control currents JS1 and JS2 that are caused to flow through the Hall element 120 in two directions by the spinning current method. As a result, the influence of the heat from the heat source 130 on an offset of the Hall element may be eliminated.

On this occasion, the center of the heat source means a point or a region having the highest temperature corresponding to a peak of isotherms drawn to represent a temperature gradient when the heat source is viewed from above.

The Hall element preferably has a shape that is line-symmetrical about the straight line along the vector sum of the Hall element control currents JS1 and JS2 in the two directions by the spinning current method.

A description is now given of the principle of the elimination of the offset of the Hall element by the above-mentioned form.

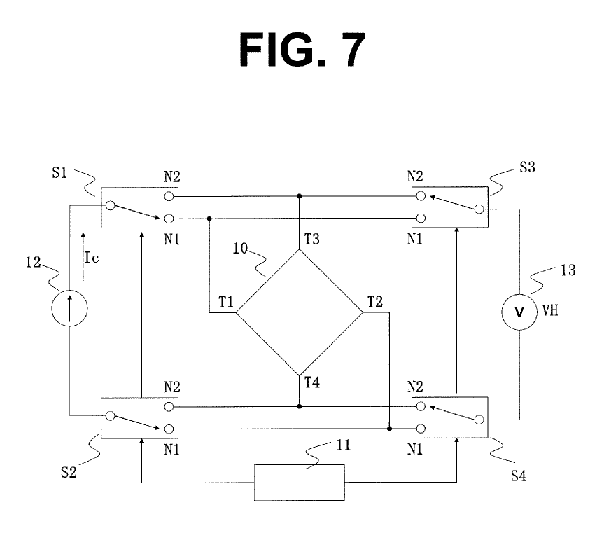

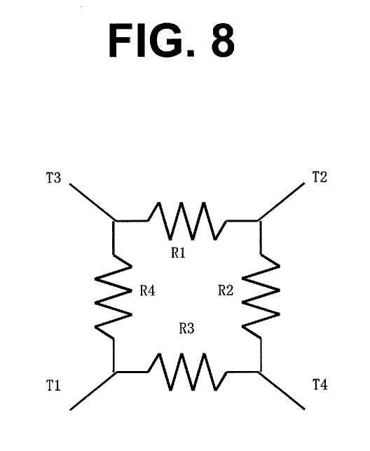

The control current input terminals and Hall voltage output terminals 110A, 110B, 110C, and 110D constructed by the N-type highly-doped regions of the Hall element 120 of FIG. 1 are respectively connected to T1, T3, T2, and T4 of FIG. 7. In an equivalent circuit of FIG. 8, it is assumed that the relationship of R2=R4 is established when the temperature is a room temperature and a temperature gradient does not exist. Then the offset may be cancelled by the spinning current. Then, when temperatures of the respective resistors are different from one another, or a temperature gradient exists, the respective resistance values are different from one another. Here, it is assumed that R2 becomes R2′, and R4 becomes R4′. When a temperature gradient exists, the relationship of R2′≠R4′ is generally established. R1≠R3 is established, and R1′≠R3′ is established even when a temperature gradient is generated.

A description is given while using the equations described above again. When the temperature is the room temperature, the temperature gradient does not exist, and a voltage Vin is applied between the one pair of terminals T1 and T2, the Hall element control current JS1 flows, and the following Hall voltage is output between the other pair of terminals T3 and T4:

Vouta=(R2*R4−R1*R3)/(R1+R4)/(R2+R3)*Vin.

Meanwhile, when the voltage Vin is applied between the terminals T3 and T4, the current JS2 flows, and the following Hall voltage is output between the terminals T1 and T2:

Voutb=(R1*R3−R2*R4)/(R3+R4)/(R1+R2)*Vin.

On this occasion, when the difference between the output voltages in the two directions is directly acquired by the spinning current, the relationship of R2=R4 is established under the state in which the temperature gradient does not exist based on the assumption, and hence the offset voltage may be made zero in the following equation:

Vouta−Voutb=(R1−R3)*(R2−R4)*(R2*R4−R1*R3)/(R1+R4)/(R2+R3)/(R3+R4)/(R1+R2)*Vin.

However, when a temperature gradient is generated, the resistance values are different from each other, and R2 becomes R2′ and R4 becomes R4′. Consequently the difference in the output voltage takes a value represented by the following equation, and may not be made zero:

Vouta′−Voutb(R1′−R3′)*(R2′−R4′)*(R2′*R4′−R1′*R3′)/(R1′+R4′)/(R2′+R3′)/(R3′+R4′)/(R1′+R2′)*Vin.

However, by setting the positional relationship between the Hall element and the heat source such that the extension line of the vector sum VC1 of the Hall element control currents JS1 and JS2 in the two directions by the spinning current method aligns with the center of the heat source 130 as illustrated in FIG. 1, the relationship of R2′=R4′ may be established while the relationship of R2=R4 is maintained even when the resistors R2 and R4 receive the influence of the heat generation to become R2′ and R4′, because the resistors R2 and R4 are arranged so as to be symmetrical about the straight line along the vector sum VC1 of the Hall element control currents JS1 and JS2 in the two directions, and hence the resistors R2 and R4 are on the same temperature gradient.

Thus, the difference between the output voltages is represented as:

Vout=Vouta′−Voutb′=0.

The offset voltage may thus be eliminated by the spinning current.

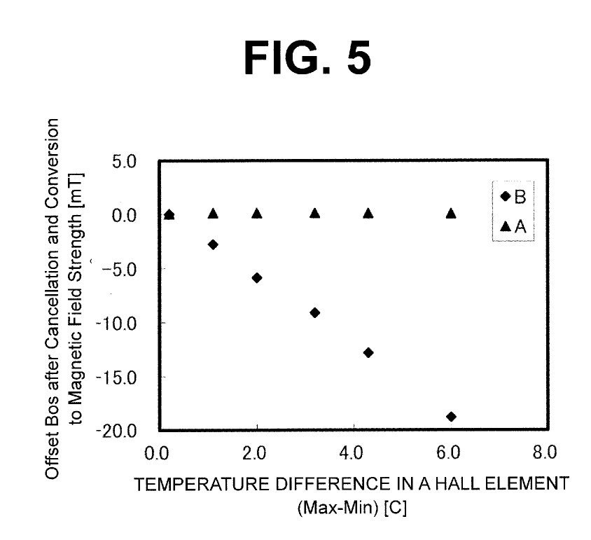

Moreover, FIG. 5 is an experiment graph for showing temperature differences between the maximum and the minimum in the Hall element and magnetic-field-equivalent values of offsets after the offsets are eliminated by the spinning current. Legends A denote measurement results of a case where the arrangement of the first embodiment illustrated in FIG. 1 is used. Legends B denote measurement results of a case where the heat source is arranged perpendicular to the Hall element control current vector sum VC1. Also from the measurement results of FIG. 5, it is appreciated that the offsets may be eliminated by setting the positional relationship between the Hall element and the heat source as illustrated in FIG. 1.

### Second Embodiment

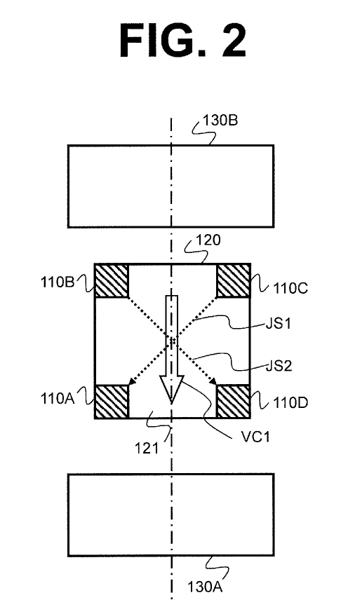

In the first embodiment, referring to FIG. 1, a description is given of the case where the number of the heat sources is one, but the number of elements that generate heat out of components of the circuit configured to control the Hall element is not limited to one. FIG. 2 is a plan view for illustrating a Hall sensor according to an embodiment of the present invention that includes a plurality of elements (heat sources) 130A and 130B that generate heat out of components of the circuit configured to control the Hall element 120.

Even in the case where the plurality of heat sources exist, the offset may be eliminated by aligning the centers of the respective heat sources 130A and 130B with an extension line of the vector sum VC1 of the Hall element control currents JS1 and JS2 in the two directions by the spinning current method.

On this occasion, the center of the heat source means a point or a region having the highest temperature corresponding to a peak of isotherms drawn to represent a temperature gradient when the heat source is viewed from above.

The Hall element preferably has a shape that is line-symmetrical about the straight line passing through the vector sum of the Hall element control currents JS1 and JS2 in the two directions by the spinning current method.

### Third Embodiment

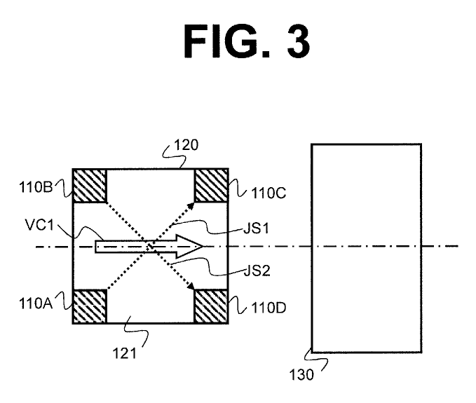

Further, as illustrated in FIG. 3, when the heat source needs to be arranged in a direction perpendicular to that of FIG. 1 and FIG. 2, the offset may be eliminated by optimizing the directions of the Hall element control currents JS1 and JS2 so as to align the center of the heat source 130 with the extension line of the vector sum VC1 of the Hall element control currents JS1 and JS2.

### Fourth Embodiment

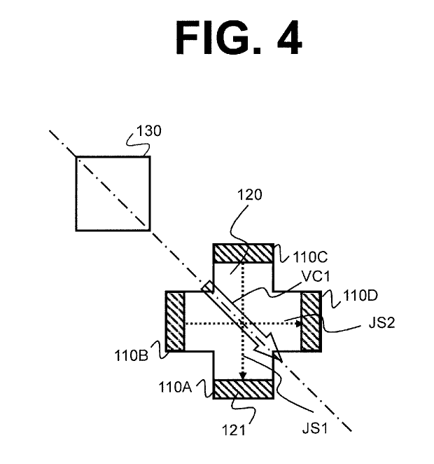

Further, the shape of the Hall element 120 is not limited to the square as illustrated in FIG. 1. As illustrated in FIG. 4, also in the Hall element 120 including the magnetism sensing portion constructed by a cross-shaped N-type doped region 121 and the Hall current control electrodes and the Hall voltage output terminals (110A to 110D) constructed by N-type highly-doped regions at four ends thereof, the influence of the heat from the heat source 130 on the offset of the Hall element may be eliminated by aligning the center of the heat source 130 with the extension line of the vector sum VC1 of the Hall element control currents JS1 and JS2.

In other words, as long as the Hall element is in a line-symmetrical shape, for example, a square or a cross shape, the offset may be eliminated by the spinning current when the center of the heat source 130 is aligned with the extension line of the vector sum VC1 of the Hall element control currents JS1 and JS2.

On this occasion, the center of the heat source means a point or a region having the highest temperature corresponding to a peak of isotherms drawn to represent a temperature gradient when the heat source is viewed from above.

The Hall element preferably has a shape that is line-symmetrical about the straight line passing through the vector sum of the currents JS1 and JS2 in the two directions by the spinning current method.

As described above, a Hall sensor that may eliminate the offset by the spinning current even when the temperature distribution in the Hall element is large, and is decreased in the chip area, thereby suppressing the cost, may be realized by decreasing the distance between the Hall element and the element that generates heat out of components of the circuit for controlling the Hall element without using a complex circuit.

What is claimed is:

1. A Hall sensor, comprising:
a Hall element arranged on a semiconductor substrate;
an element arranged around the Hall element, and serving as a heat source;
two pairs of terminals arranged on the Hall element, and serving both as control current input terminals and Hall voltage output terminals;
a first Hall element control current flowing between one pair of the terminals out of the two pairs of the terminals and a second Hall element control current flowing between another pair of the terminals crossing each other as vectors;
a shape of the Hall element which is line-symmetrical to a straight line along a vector sum of the first Hall element control current and the second Hall element control current; and
an arrangement of the element serving as the heat source in which a center of the heat source is positioned on the straight line along the vector sum of the first Hall element control current and the second Hall element control current.

2. A Hall sensor according to claim 1, wherein the Hall element comprises a magnetism sensing portion, which has a square shape or a cross shape and is symmetrical, and control current input terminals and Hall voltage output terminals, which are formed at respective vertices and ends of the magnetism sensing portion by N-type highly-doped regions to have the same shape.

3. A Hall sensor according to claim 1, wherein elimination of an offset voltage by a spinning current is applicable.
